(19) United States
(12) Patent Application Publication
(10) Pub. No.: US 2006/0032433 A1
(43) Pub. Date: Feb. 16, 2006

(54) Rapid X-ray diffraction method for structural analysis of a nano material on a surface or at an interface and for structural analysis of a solid/liquid interface, and apparatus used for the method

(75) Inventor: Osami Sakata, Sayo-gun (JP)

Correspondence Address: BANNER & WITCOFF, 1001 G STREET N W, SUITE 1100, WASHINGTON, DC, 20001, US

(73) Assignee: JAPAN SYNCHROTRON RADIATION RESEARCH INSTITUTE, Sayo-gun (JP)

(21) Appl. No.: 11/128,415

(22) Filed: May 13, 2005

(30) Foreign Application Priority Data
May 14, 2004 (JP) 2004-144473
Mar. 31, 2005 (JP) 2005-100449
Apr. 14, 2005 (JP) 2005-116712

(51) Int. Cl. C30B 23/00; C30B 25/00; C30B 28/12; C30B 28/14

(52) U.S. Cl. 117/89

(57) ABSTRACT

To characterize or evaluate ultra-fine structures such as ultra-fine nanowires grown on a substrate's crystal surface, buried ultra-fine nanolines or nanowires as sandwiched between a substrate's surface and an overlying cap layer, and thin-film crystals, or to solid-liquid interfacial structures comprising a solution and a solid, 0.1 nm or shorter-wavelength x-rays are incident on their surfaces at an angle of a few degrees or less and the diffracted x-rays are recorded with a two-dimensional x-ray detector in one action within a very short period of time, whereby the intensities of the diffracted x-rays from the ultra-fine structures or solid-liquid interfacial structures are visualized in the reciprocal lattice space and their structures are rapidly analyzed.

### BACKGROUND OF THE INVENTION

1. Field on the Invention

The present invention relates to a method for rapid x-ray structural analysis of ultra-fine structures that enables rapid acquisition of not only structural information about ultra-fine wire structures, thin films, ultra-fine nanochannels, electrodes in solution and other ultra-fine structures having the potential to be used as extremely highly efficient or sensitive semiconductor devices, sensors, light emitting devices, catalysts, chemical reaction integrated microchip mediums, DNA device carriers, and micro-fuel cell elements, but also structural information about their substrate materials.

The present invention also relates to an apparatus for rapid x-ray structural analysis of ultra-fine structures that enables rapid acquisition of not only structural information about ultra-fine wire structures, thin films, ultra-fine nanochannels, electrodes in solution and other ultra-fine structures having the potential to be used as extremely highly efficient or sensitive semiconductor devices, sensors, light emitting devices, catalysts, chemical reaction integrated microchip mediums, DNA device carriers, and micro-fuel cell elements, but also structural information about their substrate materials.

The method of the present invention for rapid x-ray structural analysis of solution/solid interfacial structures is applicable to rapid evaluation of structural changes involved in chemical reactions (electrode reactions) in general which are caused by electron transfer on an electrode's surface layer. Since the electrode reaction is accompanied by energy conversion from chemical to electrical energy (e.g. battery) and material's conversion (e.g. electrolysis and electroplating), it is possible to evaluate the structural changes that occur during the process of such conversions. For instance, in the development of wet solar cells utilizing a photoelectrode reaction and in efforts to improve the performance of photo-catalyzed electrodes and to develop new models, analysis and evaluation of the structure of an electrical double layer on the electrode's surface layer could lead to better performance of an electrolytic capacitor and a fuel cell (molten carbonate fuel cell). In addition, the advantages of rapid structural analysis could be utilized to ensure that the electrode reactions during charge and discharge of a lead-acid battery and the process of electroplating are observed real-time at an atomic scale.

2. Prior Arts

Two representative prior art techniques may be mentioned and are scanning probe microscopy (SPM) and x-ray diffraction (XRD). In SPM, information about the shape of an ultra-fine structure can be obtained from the information about the atomic-scale morphologies of the material's surface; on the other hand, information such as what concerns crystal structure that can be obtained in the present invention is not attainable by SPM. In addition, no information about a buried ultra-fine structure can be obtained by SPM. Crystallographic structural information about an ultra-fine structure formed either on a surface or at an interface is currently obtained by XRD which requires complicated equipment and a comparatively prolonged time of measurement.

In XRD, it is required that the angle of a sample be adjusted precisely with respect to an incident x-ray beam to ensure Bragg diffraction from an ultra-fine structure and that the orientation of the x-ray detector be adjusted to the direction of the resulting diffracted x-ray. To meet these requirements, one must use a diffractometer (multi-axis diffractometer) having more than three axes(usually four or more axes) of rotation in combination with tables for rough adjustment of sample alignment. In order to get crystallographic structural information such as a crystallographic coordination system and a space group, it is believed necessary to measure not only a single Bragg diffraction point but also 10 to 100 independent Bragg diffraction points and their neighborhoods. In short, the sample and the detector are adjusted to appropriate orientations and positions and the sample is rocked around the position of Bragg diffraction to collect data on diffraction intensity. The process is repeated at the 10-100 independent positions of Bragg diffraction.

In discussing the directions of incident and diffracted x-rays in a real space and their intensities, it is convenient to use the concept of a reciprocal lattice space in which the directions of the respective beams are in complete agreement with those of the real space. If the object is a crystal, Bragg diffraction conditions generally form a three-dimensional periodic array of points (reciprocal lattice points). In the reciprocal lattice space, draw a sphere with a radius of 1/λ about the origin (this sphere is called the Ewald sphere; see FIGS. 1 and 2). Since the object causes elastic scattering, λ is the wavelength of incident and diffracted x-rays. Bragg diffraction arises from adjusting the orientation of a sample such that the Ewald sphere intersects reciprocal lattice points. The incident and diffracted x-rays are expressed in vector as follows: With the end point of the incident x-rays being placed at the origin of the reciprocal lattice, the diffracted x-ray vector that originates from the start point of the vector of the incident x-ray and which ends at the reciprocal lattice point that comes to intersect the Ewald sphere as the result of adjusting the sample's orientation. The both vectors start from the center of the Ewald sphere and terminate on the sphere.

Conventionally, reciprocal lattice points are taken up one by one. The sample's orientation is adjusted to measure the diffraction intensity about the resulting reciprocal lattice point. In order to get crystallographic structural information, the procedure needs to be repeated for a plurality of reciprocal lattice points over an extended period of time using the appropriate and conventional equipment. To characterize the conventional method, one may say that the x-ray diffraction intensities distributed within a reciprocal lattice space are measured “with a fine-tooth comb”. An overall image of the diffraction intensity profile is difficult to get until after the lengthy and time-consuming measurement “with a fine-tooth comb” is completed.

The term “Bragg diffraction” is herein used in honor of the fact that the father-son team of the Braggs derived the conditions under which x-rays would be diffracted by a given crystal and it means nothing more than diffraction.

The Ewald sphere is a sphere that is defined within the reciprocal lattice space of a crystal's space lattice and mainly used to express conditions that determine the directions in which x-rays or particle rays are diffracted; if the point in the reciprocal lattice space that is at a distance of wave number 1/λ (λ is the wavelength) from the origin in a direction opposite the direction of the travel of an incident wave is written as A, the Ewald sphere has a radius of 1/λ about A. Assume a real space lattice in which the fundamental vectors are given by a₁, a₂, a₃. A second space lattice in which the fundamental vectors are given by a reciprocal system consisting of b₁, b₂, b₃ is called the reciprocal lattice with respect to the first lattice and the space described by the reciprocal system consisting of b₁, b₂, b₃ is called the reciprocal lattice space.

Electron diffraction is one of the most popular methods of evaluating surface structures but it cannot be applied to the surface of a sample in air, interface, or solution. This is because the interaction between electrons and matter is so great that electron beams are unable to reach the surface of the sample in air, interface, or solution.

### REFERENCES

Authors' names: O. Sakata, M. Takata, H. Suematsu, A. Matsuda, S. Akiba, A. Sasaki, and M. Yoshimoto
Article's name: High-energy x-ray scattering in grazing incidence from nanometer-scale oxide wires
Publisher: The American Institute of Physics
Journal's name: Applied Physics Letters
Volume: 84
Year: 2004
Pages: 4239-4241
Authors' names: O. Sakata, A. Kitano, W. Yashiro, K. Sakamoto, K. Miki, A. Matsuda, W. Hara, S. Akiba, and M. Yoshimoto
Article's name: Reciprocal-lattice space imaging of x-ray intensities diffracted from nanowires
Publisher: The Materials Research Society
Journal's name: Material Research Society Symposium Proceedings
Volume: 840
Year: 2005
Pages: Q6.4.1-Q6.4.6

### PROBLEMS TO BE SOLVED BY THE INVENTION

The problems addressed by the method of the present invention for rapid x-ray structural analysis of ultra-fine structures are: (1) to determine rapidly whether ultra-fine nanowires present either on a substrate or at a buried interface as sandwiched between a substrate and a cap layer are crystalline, as well as to analyze rapidly their crystal structure, crystal domain size (i.e. correlation length), the orientation of the ultra-fine structure with respect to the substrate crystal, and the periodicity, if any, of an array of the ultra-fine structures; (2) to analyze rapidly the crystalline structure of a thin-film crystal in thicknesses from sub-nanometers to several tens of nanometers, their crystal domain size and the proportions of any differently oriented crystal domains that may be present; (3) to obtain an overall image of diffraction intensity profile by a one-time measurement (i.e. one-time x-ray-exposure record) in order to realize the above-mentioned rapid analyses (1) and (2); (4) and to ensure that conversion of the crystal orientations of a sample to an orthogonal coordinate system as defined for the measuring system (e.g. laboratory system), which is an essential step in structural analysis and measurement of the crystal, can be realized by a single exposure to x-rays with the sample and detector fixed in position. These objects of the present invention can be attained by performing the necessary measurements without using the complicated equipment or mechanism that has been required in the conventional methods.

In the case of x-ray diffraction, an incident radiation strikes a sample at different points at the same time and if x-rays diffracted from two of such points interfere with each other, the distance between those two points is described as lying within the correlation length; since it can reasonably be said that those two points lie within the same crystal, the correlation length is related to the size of the crystal.

The problem addressed by the apparatus of the present invention for rapid x-ray structural analysis of ultra-fine structures is to implement the above-described method for rapid x-ray structural analysis of ultra-fine structures. Hence, the first requirement of the apparatus is that using the apparatus we can determine rapidly whether ultra-fine nanowires present either on a substrate or at an interface (such as a buried interface as sandwiched between a substrate and a cap layer, or a solution/crystal interface) are crystalline, as well as to analyze rapidly their crystal structure, crystal domain size (or correlation length), the orientation of the ultra-fine structure with respect to the substrate crystal, and the periodicity, if any, of an array of the ultra-fine structures.

The second requirement of the apparatus is that we can analyze rapidly the crystalline structure of thin-film crystal in thicknesses from sub-nanometers to several tens of nanometers, their crystal domain size and the proportions of any differently oriented crystal domains that may be present.

In addition, the problems addressed by the method of the present invention for rapid x-ray structural analysis of a solution/solid interfacial structure are: (1) to determine rapidly whether crystals are present at the solid/liquid interface, as well as to analyze and evaluate rapidly their crystal structure, crystal domain size (or correlation length), and the structure or arrangement of atomic or molecular ions in the interfacial electrical double layer; (2) to observe rapidly the changes in the electrode's surface structure at varying electrode potentials that accompany the electrochemical reaction occurring at the crystalline electrode surface; (3) to obtain an overall image of diffraction intensity profile by a one-time measurement (i.e. one-time x-ray-exposure record) in order to realize the above-mentioned rapid analyses (1) and (2); (4) to ensure that conversion of the crystal orientations of a sample to an orthogonal coordinate system as defined for the measuring system (e.g. laboratory system), which is an essential step in structural analysis and measurement of the crystal, can be realized by a single exposure to x-rays with the sample and detector fixed in position; and (5) to perform the necessary measurements without using the complicated equipment or mechanism that has been required in the conventional methods.

### SUMMARY OF THE INVENTION

### MEANS FOR SOLVING THE PROBLEMS

The method of the present invention for rapid x-ray structural analysis of ultra-fine structures has as an object rapid acquisition of crystallographic structural information for the ultra-fine structures (as to whether they are crystalline, as well as concerning their crystal structure, crystal domain size (correlation length), the orientations to the substrate, and the periodicity, if any, of an array of the ultra-fine structures).

If the ultra-fine structures are in the form of wires, the Bragg diffraction conditions resulting from the crystalline ultra-fine structures are for the shape of a sheet (a plane having a finite area), or sheet-shape diffraction conditions (FIG. 1). If the ultra-fine structures are in the form of a thin film, the emanating diffraction conditions are for the shape of a rod (having a finite length), or rod-shape diffraction conditions (FIG. 2). The present invention takes particular note of those unique shapes and is characterized in that an overall image of x-ray intensities in a reciprocal lattice space resulting from the ultra-fine structures can be obtained by a single measurement (i.e. one-time x-ray-exposure record) using monochromatic high-energy x-rays not longer than 0.1 nanometer.

The invention's method of structural analysis is characterized in that the lines along which the above-mentioned sheet- or rod-shape Bragg diffraction conditions intersect the Ewald sphere (which is in a reciprocal lattice space such that the end point of a wave number vector for incident x-rays passes through the origin of that space and which has a radius equal to the reciprocal of the wavelength of the incident x-rays, with the center being located at the start point of its vector) or the points of such intersection are visualized as diffraction images.

To attain this objective, 0.1 nm or shorter-wavelength x-rays are used as incident x-rays; in addition, the diffraction images emanating from the ultra-fine structures are recorded in a two-dimensional detector (FIG. 3). In this instance, no complicated equipment or mechanism is used to adjust the orientations of the sample and detector. The device that needs to be used is composed of a sample adjusting table and a two-dimensional x-ray detector. The table can control the angle between the sample surface and the incident x-rays with a precision of about 0.1 degree and adjust sample height as well.

The overall pattern of the recorded diffraction images is uniquely related to the internal crystal structure of the ultra-fine structures and their orientations to the substrate. Therefore, studying that pattern, one can determine the internal crystal structure of the ultra-fine structures and their orientations to the substrate. In addition, the angular widths of the individual diffraction images and fine structures in the images are inversely proportional to the crystal domain size (that is, correlation length) and the periodicity, if any, of an array of the ultra-fine structures, respectively. By analyzing the angular widths of the individual diffraction images and the fine structures in the images, one can obtain the crystal domain size (i.e. correlation length) and the periodicity, if any, of an array of the ultra-fine structures. In each of FIGS. 5 and 6, one of the spots in the left-hand picture is magnified in the right-hand picture, and by so doing, one can rapidly obtain the crystallite size and the periodicity of the average gap of the stripes of the nanometer-scale wires that we investigate.

The apparatus of the present invention for rapid x-ray structural analysis of ultra-fine structures has as an object rapid acquisition of crystallographic structural information for ultra-fine structures present either on a surface or at an interface (as to whether they are crystalline, as well as concerning their crystal structure, crystallite size, correlation length, the orientations to the substrate, and the periodicity, if any, of an array of the ultra-fine structures).

If the ultra-fine structures are in the form of wires, the Bragg diffraction conditions resulting from the crystalline ultra-fine structures are for the shape of a sheet (a plane having a finite area); and if the ultra-fine structures are in the form of a thin film, the emanating diffraction conditions are for the shape of a rod (having a finite length). The present invention takes particular note of those unique shapes and provides the apparatus which is characterized in that an overall image of x-ray intensities in a reciprocal lattice space as obtained from ultra-fine structures can be obtained by a single measurement (i.e. one-time x-ray-exposure record) using monochromatic high-energy x-rays with wavelengths no longer than 0.1 nanometer but without rotating the sample and detector.

The invention's apparatus for structural analysis is characterized in that the lines along which the above-mentioned sheet- or rod-shape Bragg diffraction conditions intersect the Ewald sphere (which is in a reciprocal lattice space such that the end point of a wave number vector for incident x-rays passes through the origin of that space and which has a radius equal to the reciprocal of the wavelength of the incident x-rays, with the center being located at the start point of its vector) or the points of such intersection are visualized as diffraction images.

To attain this objective, 0.1 nm or shorter-wavelength x-rays are used as incident x-rays; in addition, the diffraction images emanating from the ultra-fine structures are recorded using a two-dimensional detector. In this instance, no complicated equipment or mechanism is used to adjust the orientations of the sample and detector, and neither the sample nor the detector is rotated. As shown in FIG. 4, the apparatus of the invention consists of an incident angle changing mechanism that controls the angle between the sample surface and the incident x-rays, a table that adjusts the height of that mechanism, a table for adjusting the height of the sample, a two-dimensional detector, a support of the two-dimensional detector, and a sample holder. The precision of angle control must be at least comparable to the critical angle for total reflection from the sample. The precision and reproducibility of sample height adjustment was 0.1 millimeter or less. If need be, a mechanism for effecting rotation about the normal to the sample surface and a two-way sample transporting table may be added.

The method of the present invention for rapid x-ray structural analysis of a solution/solid interfacial structure has as an object rapid acquisition of crystallographic structural information for the solid/liquid interface, such as whether it is crystalline, as well as concerning its crystal structure, crystal domain size, and correlation length.

If the solid/liquid interfacial structure is in a two-dimensional form, the resultant diffraction conditions are for the shape of a rod. If the structure is in the form of a wire, the Bragg diffraction conditions resulting from the structure are for the shape of a sheet (a plane having a finite area) in a reciprocal lattice space. The present invention takes particular note of those unique shapes and is characterized in that an overall image of x-ray intensities in a reciprocal lattice space that results from a solid/liquid interfacial structure can be obtained by a single measurement (i.e. one-time x-ray-exposure record).

The invention's method of structural analysis is characterized in that the lines along which the above-mentioned rod- or sheet-shape Bragg diffraction conditions intersect the Ewald sphere (which is in a reciprocal lattice space such that the end point of a wave number vector for incident x-rays passes through the origin of that space and which has a radius equal to the reciprocal of the wavelength of the incident x-rays, with the center being located at the start point of its vector) or the points of such intersection are visualized as diffraction images.

To attain this objective, 0.1 nm or shorter-wavelength x-rays are used as incident x-rays whereas the largest possible Ewald sphere is used and the diffraction images emanating from the interfacial structure are recorded using a two-dimensional detector. In this instance, no complicated equipment or mechanism is used to adjust the orientations of the sample and detector. Thus, in the method of the invention, an apparatus of a simple mechanism is used and consists of a table with which the angle between the sample surface and the incident x-rays can be controlled with a precision of about 0.1 degree and which also adjusts the sample height, as well as a two-dimensional detector and a support of the two-dimensional detector.

The overall pattern of the recorded diffraction images is uniquely related to the solid/liquid interfacial structure. Therefore, studying that pattern, one can judge whether any crystal is present at the solid/liquid interface and, if so, its crystal structure can be determined. In addition, by analyzing the internal state of the individual diffraction images (spots), one can rapidly obtain the crystal domain size or correlation length. In FIG. 17, one of the spots in the right-hand picture is magnified in the left-hand picture, and by so doing, one can rapidly obtain the crystallite size or correlation length.

### EFFECT OF THE INVENTION

The method of the present invention for rapid x-ray structural analysis of ultra-fine structures is intended to be applied to ultra-fine nanowires grown on a substrate crystal surface, and buried ultra-fine nanowires as sandwiched between a substrate surface and an overlying cap layer, as well as ultra-fine structures such as thin-film crystals. The present invention relates to a method that determines the crystal structures of those structures, crystal domain size (or correlation length), the orientations to the substrate, and the periodicity, if any, of an array of the ultra-fine structures.

To characterize ultra-fine nanowires grown on a substrate crystal surface, and buried ultra-fine nanowires as sandwiched between a substrate surface and an overlying cap layer, as well as ultra-fine structures such as thin-film crystals, 0.1 nm or shorter-wavelength x-rays are applied to their surfaces at angles of a few degrees and less and the diffracted x-rays are recorded with a two-dimensional x-ray detector in one action within a very short period of time. As the result, the intensities of the diffracted x-rays from the ultra-fine structures are visualized in the reciprocal lattice space and their structures can be rapidly analyzed.

Conversion of the crystal orientations of the sample to an orthogonal coordinate system as defined for the measuring system (e.g. laboratory system) is an essential step in structural analysis and measurement of the crystal and this can be achieved by examining the overall pattern of diffraction images that are obtained by a single exposure to x-rays with the sample and detector fixed in angle and position.

To realize rapid analysis, the apparatus of the present invention for rapid x-ray structural analysis of ultra-fine structures is adapted to provide an overall image of a diffraction intensity profile by a single measurement (i.e. one-time x-ray-exposure record) without rotating the sample. Thus, the apparatus has no need to use the complicated equipment or mechanism that is necessary for the conventional apparatuses. In short, in the intended measurements, the apparatus of the present invention does not require any complicated mechanism such as a rotating mechanism around more than two axes for adjusting the sample orientation that has been required in the conventional apparatuses.

In addition, the method of the present invention for rapid x-ray structural analysis of a solution/solid interfacial structure does not use any complicated device (multi-axis diffractometer) that adjusts the orientations of a sample and detector. It is capable of rapid evaluation and analysis at an atomic level of structural changes involved in chemical reactions (electrode reactions) in general which are caused by electron transfer on an electrode's surface layer. The electrode reaction is accompanied by energy conversion from chemical to electrical energy or by material's conversion. These conversions are utilized in various devices such as batteries (including rechargeable batteries and fuel cells), electrolytic capacitors and photocatalysts. By using the method of the present invention, the relationship between the functions of these devices and their structures at a nano-scale can be known efficiently. This contributes to reducing the costs for developing those devices.

### BRIEF DESCRIPTION OF THE DRAWINGS

FIG. 1 is a diagram showing sheet-shape Bragg diffraction conditions that result from crystalline ultra-fine structures in wire form;

FIG. 2 is a diagram showing rod-shape Bragg diffraction conditions that result from crystalline ultra-fine structures in thin film form;

FIG. 3 shows a layout for measuring means;

FIG. 4 is a photograph of the apparatus for rapid x-ray structural analysis of ultra-fine structures according to the present ivnention;

FIG. 5 is a diagram showing the pattern of diffraction images obtained when x-rays were incident normal to ultra-fine nickel oxide (NiO) nanowires grown on a sapphire single crystal(0001);

FIG. 6 is a diagram showing the pattern of diffraction images obtained when x-rays were incident parallel to ultra-fine nickel oxide (NiO) nanowires grown on a sapphire single crystal (0001);

FIG. 7 is a diagram showing the experimental diffraction pattern obtained when x-rays were incident normal to buried ultra-fine bismuth nanolines as sandwiched between a single-crystal silicon (001) substrate and an overlying silicon epitaxial cap layer, with the left-hand picture being a magnification of the experimental diffraction pattern from the interfacial, intact bismuth nanolines with a 2× n superstructure;

FIG. 8 is a diagram showing the experimental diffraction pattern obtained when x-rays were incident parallel to buried ultra-fine bismuth nanolines as sandwiched between a single-crystal silicon (001) substrate and an overlying silicon epitaxial cap layer (the sample was the same as that shown in FIG. 7, except that it was azimuthally rotated clockwise through 90 degrees; all nanolines were found to have grown in alignment in one direction);

FIG. 9 is a diagram showing the pattern of diffraction images obtained when x-rays were incident substantially normal to buried ultra-fine bismuth nanowires as sandwiched between a single-crystal sapphire (001) substrate and an overlying silicon amorphous cap layer;

FIG. 10 is a diagram showing the experimental pattern of diffraction images from a 50-nm-thin film of bismuth titanium oxide (Bi₄Ti₃O₁₂) grown on a titanium dioxide (TiO₂) single crystal (101), provided that the incident angle was 0.2 degrees and that diffraction images were recorded on a planar two-dimensional detector;

FIG. 11 is a diagram showing a simulated (calculated) pattern of diffraction images from a monoclinic crystal structure, which obviously agrees with the experimental pattern;

FIG. 12 is a diagram showing a simulated (calculated) pattern of diffraction images from an orthorhombic crystal structure, which has partial disagreement with the experimental pattern (as marked by crosses missing in this calculated pattern);

FIG. 13 is a diagram showing the experimental pattern of diffraction images from a 3-nm-thin film of bismuth titanium oxide (Bi₄Ti₃O₁₂) grown on a titanium dioxide (TiO₂) single crystal (101);

FIG. 14 is a diagram showing the experimental pattern of diffraction images from a 50-nm-thin film of bismuth titanium oxide (Bi₄Ti₃O₁₂) grown on a titanium dioxide (TiO₂) single crystal (101), provided that the incident angle was 0.1 degree and that diffraction images were recorded on a cylindrical two-dimensional detector;

FIG. 15 is a reciprocal lattice space presentation of the layout of the sample used in Example 9 as it was projected onto a reciprocal lattice plane parallel to the gold (111)c (here, the subscript C in indicates that the indices are based on the cubic system notation) surface, with the notation being based on the surface lattice of a hexagonal crystal, and incident x-rays were parallel to [−100] and the length of the incident wave number vector (20 nm⁻¹) was about five times as much as the unit length of the surface lattice (4 nm⁻¹);

FIG. 16 is a cyclic voltammogram (current density vs. voltage (CV) profile) of the gold (111)c electrode surface in 0.5 M sulfuric acid solution (H₂SO₄) (which may be used to show the voltage conditions for the diffraction patterns shown in FIGS. 17 and 18), with the reference electrode being made of mercury (Hg)|mercury sulfate (Hg₂SO₄);

FIG. 17 is a diagram showing the experimental diffraction pattern from a 1×1 structure of the gold (111)c electrode surface in 0.5 M sulfuric acid solution, as recorded on a two-dimensional x-ray detector which was fixed in position together with the sample while the latter was exposed to x-rays for 5 minutes; and

FIG. 18 is a diagram showing the changes in diffraction pattern that accompanied the process of phase transition (from 23×√3 to 1×1 structure) at the solution/electrode interface (gold electrode's surface in solution), with the applied voltage being within the range A indicated in FIG. 16 and the pattern emanating from the vicinity of the rod-shape 0 1 6.3 diffraction condition, as recorded on a two-dimensional x-ray detector which was fixed in position together with the sample while the latter was exposed to x-rays for 5 minutes.

### DETAILED DESCRIPTION OF THE INVENTION

The method of the present invention for rapid x-ray structural analysis of ultra-fine structures is intended to be applied to ultra-fine nanowires grown on a substrate crystal surface, and buried ultra-fine nanowires as sandwiched between a substrate surface and an overlying cap layer, as well as ultra-fine structures such as thin-film crystals. The present invention relates to a method that determines the crystal structures of those structures, crystal domain size (or correlation length), the orientations to the substrate, and the periodicity, if any, of an array of the ultra-fine structures.

To characterize ultra-fine nanowires grown on a substrate crystal surface, and buried ultra-fine nanowires as sandwiched between a substrate surface and an overlying cap layer, as well as ultra-fine structures such as thin-film crystals, 0.1 nm or shorter-wavelength x-rays are applied to their surfaces at angles of a few degrees and less and the diffracted x-rays are recorded with a two-dimensional x-ray detector in one action within a very short period of time. As the result, the intensities of the diffracted x-rays from the ultra-fine structures are visualized in the reciprocal lattice space and their structures can be rapidly analyzed.

Conversion of the crystal orientations of the sample to an orthogonal coordinate system as defined for the measuring system (e.g. laboratory system) is an essential step in structural analysis and measurement of the crystal. The present invention relates to a method for achieving this essential step by a single exposure to X-rays with the sample and detector fixed in position.

In the apparatus of the present invention for rapid x-ray structural analysis of ultra-fine structures, the angular precision of the rotating mechanism that controls the angle the sample surface forms with an incident x-ray was 0.0004 degrees/pulse and its stroke was ±5 degrees. The precision of the height adjusting table associated with the incident angle changing mechanism was 1 μm/pulse and its stroke was ±50 mm. The precision of the sample height-adjusting table was 0.1 μm/pulse and its stroke was ±5 mm.

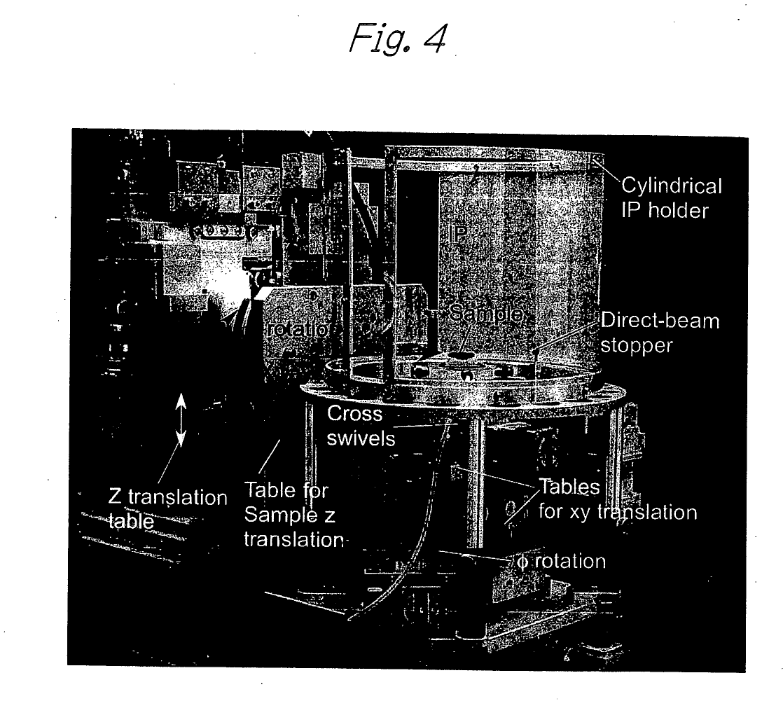

The two-dimensional detector is used as installed in a cylinder of which center axis passes through the sample position and which can be installed to the vertical position (see FIG. 4) or horizontal position. The cylinder is not rotated. However, the detector can be installed at any angular position within the range of 360 degrees about the axis of the cylindrical holder. In the case of a flat two-dimensional detector, it may be operated in any desired position. Still another feature can be installed such that it permits the addition of a sample rotary mechanism around the normal to the sample surface and a cross table for sample transportation. FIG. 4 shows the case where a cylindrical two-dimensional detector (colored blue) is mounted in a cylindrical holder installed on a vertical axis.

In the apparatus of the invention, the sample is placed on the sample holder and can be moved up and down by means of the sample height-adjusting table. The sample can also be moved in a horizontal direction by manipulating the sample transportation table. In FIG. 4, by rotating a mechanism for sample rotation around the horizontal axis one can control an incident angle between the sample surface and incident x-rays parallel to a horizontal direction. Since this incident angle changing mechanism can be moved up and down by means of the associated height adjusting table, the center of rotation of the incident angle changing mechanism can be brought into complete agreement with the height of the incident x-rays. The two-dimensional detector is attached to a cylindrical sample holder.

In addition, the method of the present invention for rapid x-ray structural analysis of a solution/solid interfacial structure is intended to be applied to two- or one-dimensional ultra-fine structures that are present on a solid surface in solution, namely, at the solution/solid interface. The invention relates to a method for determining the crystal structures of those ultra-fine structures, as well as their crystal domain size (correlation length), and the structure of atomic or molecular ions in the interfacial double layer. The invention also relates to a method for determining the process of changes in the electrode's surface structure at varying electrode potentials that accompany the electrochemical reaction occurring at the crystalline electrode surface.

Conversion of the crystal orientations of the sample to an orthogonal coordinate system as defined for the measuring system (e.g. laboratory system) is an essential step in structural analysis and measurement of the crystal. The present invention relates to a method for achieving this essential step by a single exposure to x-rays with the sample and detector fixed in angle and position.

To characterize two- or one-dimensional ultra-fine structures that are present on a solid surface in solution, namely, at the solution/solid interface, 0.1 nm or shorter-wavelength x-rays are applied to their surfaces at an angle of a few degrees and less (an angle of 2.3 degrees was used in Example 9) and the diffracted x-rays are recorded with a two-dimensional x-ray detector in one action within a very short period of time. As the result, the intensities of the diffracted x-rays from the ultra-fine structures of interest are visualized in the reciprocal lattice space and their structures can be rapidly analyzed.

The following examples are provided for further illustrating the present invention.

### EXAMPLES

### Example 1

Case 1 of Ultra-Fine Nanowires Grown on a Substrate Crystal Surface (Method of Rapid X-Ray Structural Analysis of Ultra-Fine Structures)

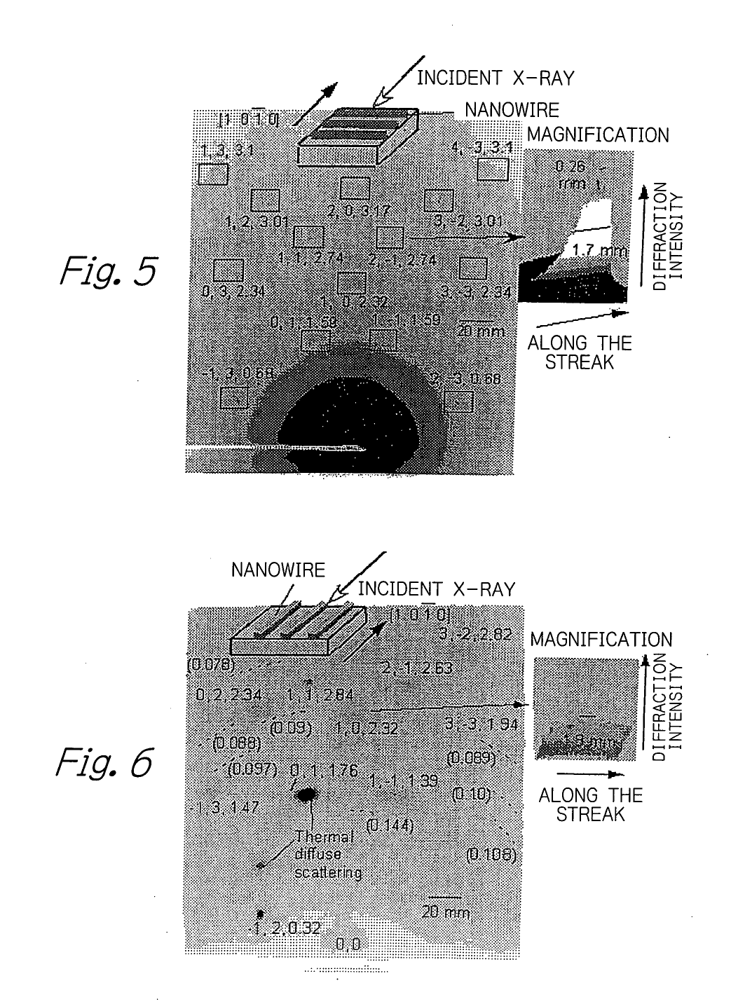

In this Example, ultra-fine nickel oxide (NiO) nanowires (0.5 nm high) were epitaxially deposited on a sapphire single crystal (0001) and x-rays were incident substantially normal to those nanowires. The incident x-rays had a wavelength of 0.05 nm and formed an angle of 0.05 degrees with the sample surface. An imaging plate as a two-dimensional x-ray detector was set perpendicular to the incident x-rays. The results are shown in FIG. 5.

From the overall pattern of diffraction images, it was found that the ultra-fine nanowires under test had a hexagonal structure, with the crystal lattice parameters having lengths of 0.476, 0.476 and 0.421 nm and angles of 90, 90 and 120 degrees. It was also found that those nanowires were perpendicular to the [1 0-1 0] direction of the sapphire substrate. From the width of one diffraction image (as magnified in the inset), the size of crystal domains in the nanowires was estimated to be 15 nm; from the peak-to-peak distance in the diffraction image, the period between adjacent nanowires was estimated to be 46 nm. Each sequence of three numerals in FIG. 5 expresses the position at which the center of each diffraction image is located in the reciprocal-lattice-space coordinate system.

### Example 2

### Case 2 of Ultra-Fine Nanowires Grown on a Substrate Crystal Surface (Method of Rapid X-Ray Structural Analysis of Ultra-Fine Structures)

In this Example, ultra-fine nickel oxide (NiO) nanowires (0.5 nm high) were deposited on a sapphire single crystal (0001) and x-rays were incident substantially parallel to those nanowires. The sample was prepared under almost the same conditions as in Example 1. The incident x-rays having a wavelength of 0.05 nm formed an angle of 0.2 degrees with the sample surface. An imaging plate as a two-dimensional x-ray detector was set perpendicular to the incident x-rays. The results are shown in FIG. 6.

From the overall pattern of diffraction images, it was found that the ultra-fine nanowires under test had a hexagonal structure, with the crystal lattice parameters having lengths of 0.476, 0.476 and 0.421 nm and angles of 90, 90 and 120 degrees. It was also found that those nanowires were not completely parallel to, but 5 degrees offset from, the [1 0-1 0] direction of the sapphire substrate. From the width of one diffraction image (as magnified in the inset), the size of crystal domains in the nanowires was estimated to be 14 nm. Each sequence of three numerals in FIG. 6 expresses the position at which the center of each diffraction image is located in the reciprocal-lattice-space coordinate system.

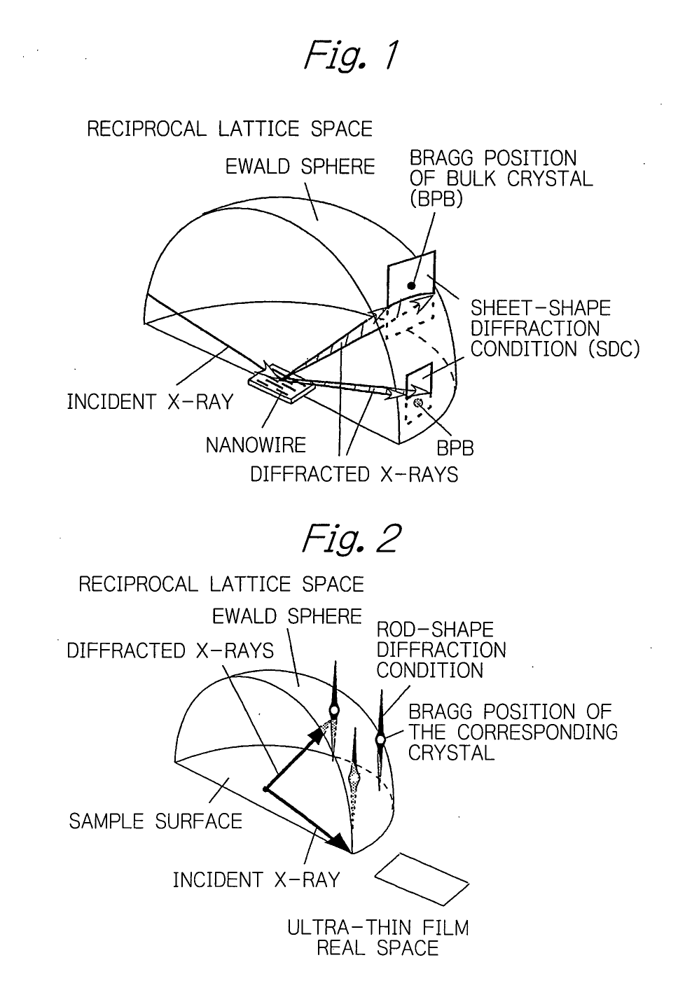

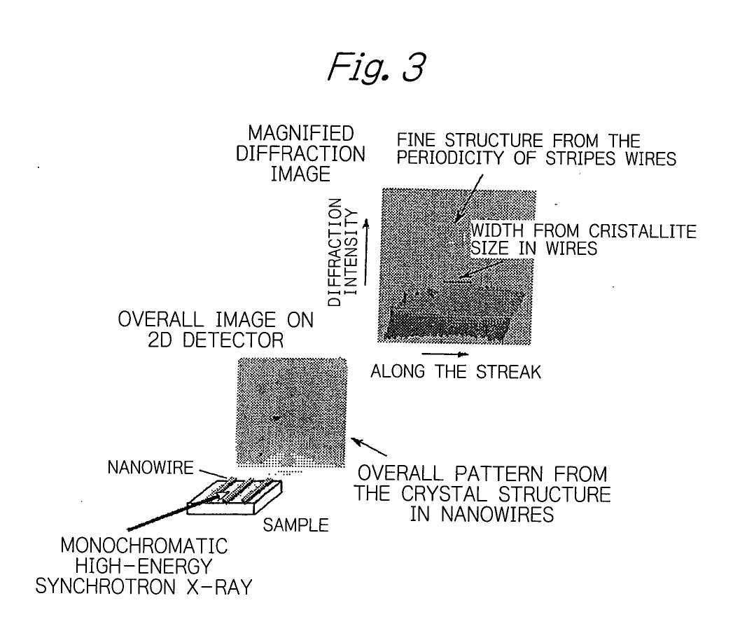

The individual diffraction images formed partial circular arcs about the center which was the point of intersection between the incident radiation and the imaging plate (below the point 0,0 in FIG. 6). This agrees with the description of FIG. 1 indicating that the diffraction conditions for the ultra-fine nanowires are of sheet-shape. If NiO had not been in wire form but powder crystals, the individual diffraction images should have formed semicircles whose radii are demarcated by calculated broken arcs (called Debye-Sherrer rings). However, no parts of the recorded circular arcs were found to be in agreement with the calculated broken arcs. This provides another evidence that supports that the diffraction conditions for the ultra-fine nanowires are of sheet-shape.

### Example 3

### Case 1 of Buried Ultra-Fine Nanolines Sandwiched Between a Substrate Crystal and an Overlying Cap Layer (Method of Rapid X-Ray Structural Analysis of Ultra-Fine Structures) (Apparatus for Rapid X-Ray Structural Analysis of Ultra-Fine Structures)

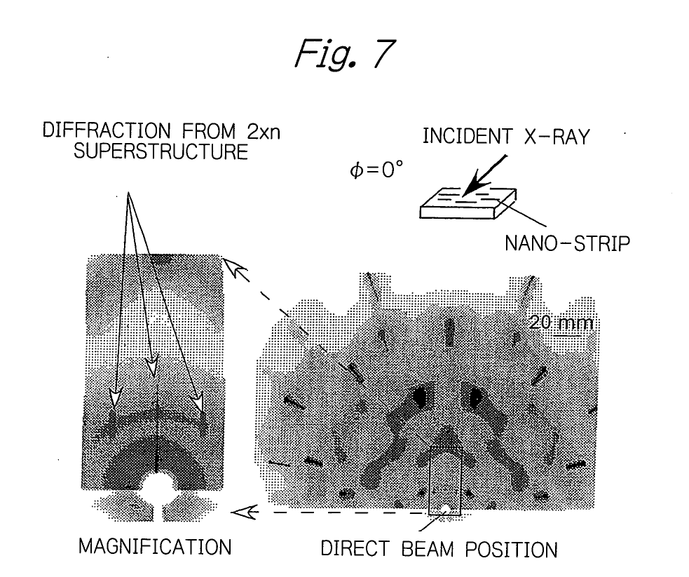

In this Example, bismuth (Bi) nanolines (monolayer in height, 1.5 nm in width, and ca. 400 nm in length) were grown on a silicon (Si) single-crystal (001) surface, a silicon (Si) cap layer was epitaxially grown in a thickness of about 10 nm over those nanolines, and x-rays were incident normal to the nanolines. The incident x-rays (with a wavelength of 0.05 nm) formed an angle of 0.1 degree with the sample surface. A cylindrical imaging plate as a two-dimensional x-ray detector was installed in such a way that its axis of the cylinder holder was parallel to the vertical axis passing through the sample. The results are shown in FIG. 7. Both the sample and the detector were fixed in angle and position during x-ray exposure. The right-hand picture of FIG. 7 shows the overall pattern of diffraction images from a 2-minute x-ray exposure. The rectangular portion of the picture is magnified in the left-hand picture. X-ray diffraction was able to be observed from a 2×n superstructure whose period was twice the period for the silicon substrate. This was the first discovery of the fact that even after the formation of the cap layer, a 2×n superstructure remained without loss of structure. Another finding is that the nanolines retained the two-by periodicity along their length. From the thickness of each diffraction line, the nanolines were estimated to have an overall length of about 100 nm in the direction of their axis. From the symmetry of the overall pattern, the incident x-rays were found to be parallel to the [010] direction defined on the basis of the surface lattice (i.e., parallel to the [110]_{c} direction of the substrate by the cubic notation). This corresponds to having done the job of converting the crystal orientation of the sample to an orthogonal coordinate system as defined for the measuring system (the job is commonly described as determining a UB matrix). In other words, a UB matrix has been determined by a single exposure to x-rays with the sample and the detector fixed in angle and position.

### Example 4

### Case 2 of Buried Ultra-Fine Nanolines Sandwiched Between a Substrate Crystal and an Overlying Cap Layer (Method of Rapid X-Ray Structural Analysis of Ultra-Fine Structures) (Apparatus for Rapid X-Ray Structural Analysis of Ultra-Fine Structures)

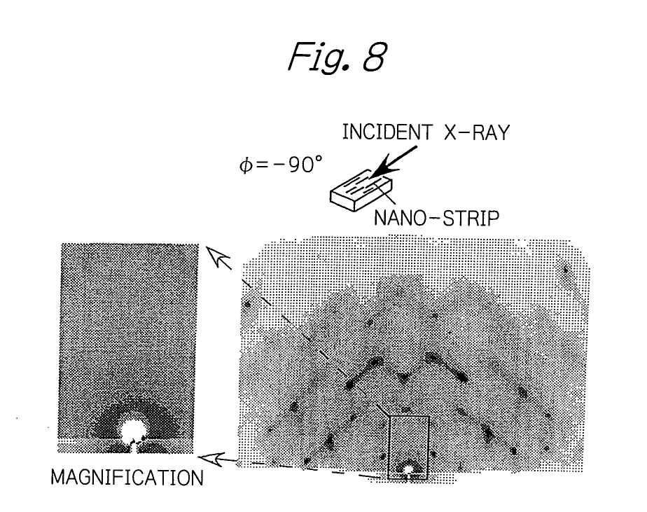

In this Example, bismuth (Bi) nanolines were grown on a silicon (Si) single-crystal (001) surface, a silicon (Si) cap layer was epitaxially grown in a thickness of about 10 nm over those nanolines, and x-rays were incident parallel to the nanolines. In other words, the same sample as prepared in Example 3 was rotated clockwise through 90 degrees in a horizontal plane. The incident x-rays (with a wavelength of 0.05 nm) formed an angle of 0.1 degree with the sample surface. A cylindrical imaging plate as a two-dimensional x-ray detector was installed in such a way that its axis of the cylindrical holder was parallel to the vertical axis passing through the sample. The results are shown in FIG. 8. Both the sample and the detector were fixed in angle and position during x-ray exposure. The right-hand picture of FIG. 8 shows the overall pattern of diffraction images from a 2-minute x-ray exposure. The rectangular portion of the picture is magnified in the left-hand picture. In Example 3, x-ray diffraction was able to be observed from a 2×n superstructure with a period twice that of the substrate but this was not the case in Example 4. From this fact, it was found that all nanolines had grown in alignment in one direction, which was found to be parallel to the [100] direction of the substrate. The coordinate system used was based on the surface lattice.

### Example 5

### Case 1 of Buried Ultra-Fine Nanolines Sandwiched Between a Substrate Crystal and an Overlying Cap Layer (Method of Rapid X-Ray Structural Analysis of Ultra-Fine Structures) (Apparatus for Rapid X-Ray Structural Analysis of Ultra-Fine Structures)

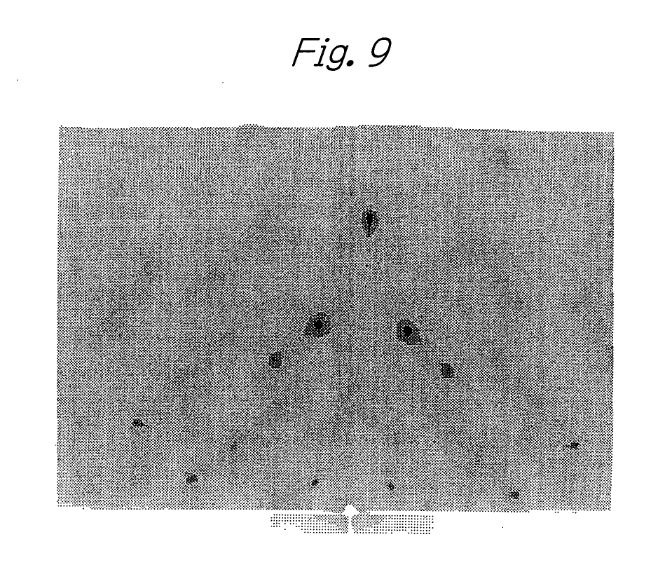

In this Example, bismuth (Bi) nanolines were grown on a silicon (Si) single-crystal (001) surface, a silicon (Si) cap layer was amorphously grown in a thickness of about 10 nm over those nanolines, and x-rays were incident substantially parallel to the nanowires. The incident x-rays (with a wavelength of 0.05 nm) formed an angle of 0.1 degree with the sample surface. A cylindrical imaging plate as a two-dimensional x-ray detector was installed in such a way that its axis of the cylindrical holder was parallel to the vertical axis passing through the sample. The results are shown in FIG. 9. The diffraction images were from the silicon substrate or an epitaxial silicon cap layer. Unlike the epitaxial cap layer formed in Example 3, the sample covered with the amorphous silicon cap layer did not retain the 1×2 structure of the nanolines.

### Example 6

### Case of Thin Film (Method of Rapid X-Ray Structural Analysis of Ultra-Fine Structures)

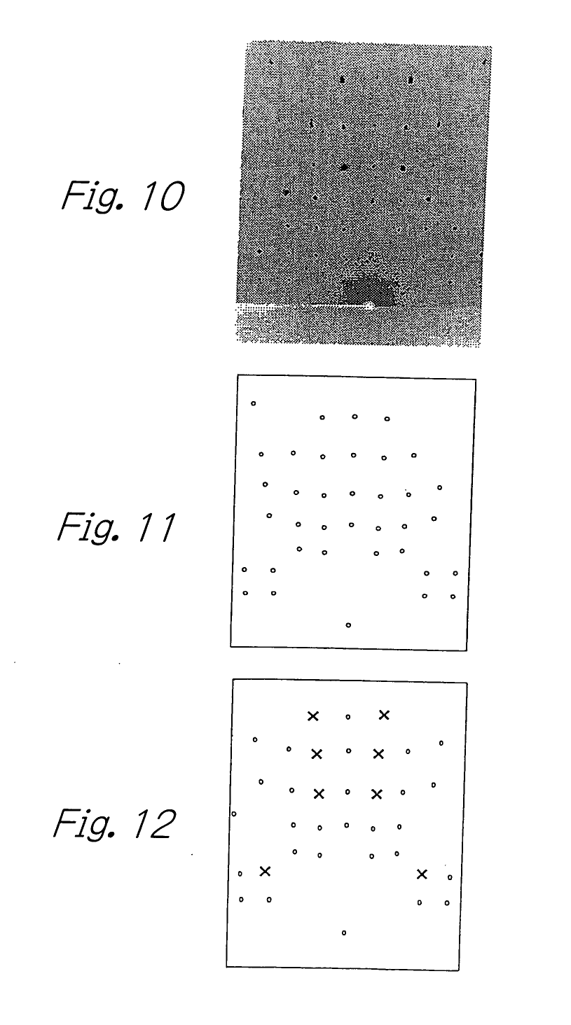

In this Example, a 50-nm-thin film of bismuth titanium oxide (Bi₄Ti₃O₁₂) was grown on a titanium dioxide (TiO₂) single crystal (101) and x-rays (with a wavelength of 0.05 nm) were incident at an angle of 0.2 degrees with the sample surface. An imaging plate as a flat two-dimensional x-ray detector was installed perpendicular to the incident x-rays. The results are shown in FIG. 10. To determine the crystal structure of the thin film, diffraction images were simulated for monoclinic and orthorhombic systems; the results of simulation are shown in FIG. 11 (monoclinic) and FIG. 12 (orthorhombic). If the crystal system of the thin film had been orthorhombic, the diffraction images marked by crosses in FIG. 12 would not have appeared on account of the extinction rule for the crystallographic space groups. Hence, it was postulated that the bismuth titanium oxide thin film belonged to the monoclinic system. In addition, comparison was made with simulated (calculated) diagrams to determine the lattice constants of the crystal structure, which were found to be 0.0545, 0.0541 and 3.28 nm.

### Example 7

### Case of Ultra-Thin Film (Method of Rapid X-Ray Structural Analysis of Ultra-Fine Structures)

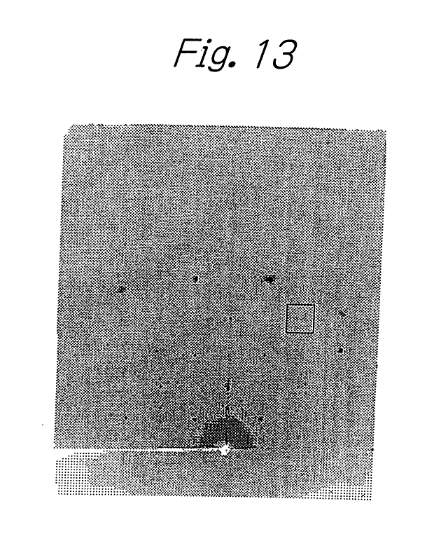

In this Example, a 3-nm-thin film of bismuth titanium oxide (Bi₄Ti₃O₁₂) was grown on a titanium dioxide (TiO₂) single crystal (101) and x-rays (with a wavelength of 0.05 nm) were incident at an angle of 0.1 degree with the sample surface. An imaging plate as a planar two-dimensional x-ray detector was installed perpendicular to the incident x-rays. The results are shown in FIG. 13. As in Example 6, comparison was made with simulated diagrams to have a speculation that the ultra-thin (3 nm) bismuth titanium oxide film also belonged to the monoclinic system. Looking at the diffraction image within the rectangle in FIG. 13, it was found to have split into two fragments in a longitudinal direction. This is due to the coexistence of two domains, a domain having the a axis perpendicular to the sample surface and b domain having the b axis perpendicular to the sample surface. From the intensity of the diffraction image in the rectangle, the domain ratio was found to be approximately 1:1.

### Example 8

### Case of Thin Film (Apparatus for Rapid X-Ray Structural Analysis of Ultra-Fine Structures)

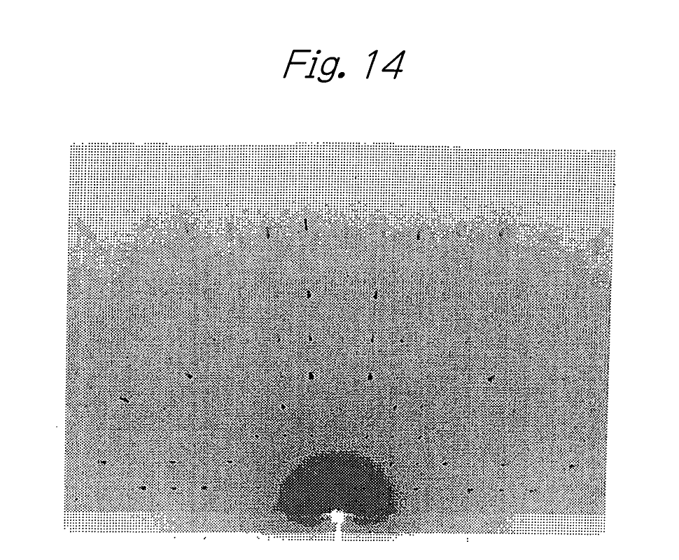

In this Example, a 50-nm-thin film of bismuth titanium oxide (Bi₄Ti₃O₁₂) was grown on a titanium dioxide (TiO₂) single crystal (101) and x-rays (with a wavelength of 0.05 nm) were incident at an angle of 0.1 degree with the sample surface. An imaging plate was used as a two-dimensional x-ray detector. The results are shown in FIG. 14. Both the sample and the detector were fixed in angle and position during x-ray exposure. The x-ray exposure time was 3 minutes.

The present inventor was the first to succeed in recording a large number of x-ray diffraction spots without rotating the sample or the detector. From the symmetry of the overall pattern, the incident x-rays were found to be parallel to the [001] direction of the bismuth titanium oxide film investigated. This corresponds to having done the job of converting the crystal orientation of the sample to an orthogonal coordinate system as defined for the measuring system (the job is commonly described as determining a UB matrix). In other words, a UB matrix has been determined by a single exposure to x-rays with the sample and the detector fixed in angle and position.

### Example 9

### Case of Surface Superstructure of a Gold (111)_{c} electrode in sulfuric acid solution (apparatus for rapid x-ray structural analysis of ultra-fine structures) (method of rapid x-ray structural analysis of solution/solid interfacial structure)

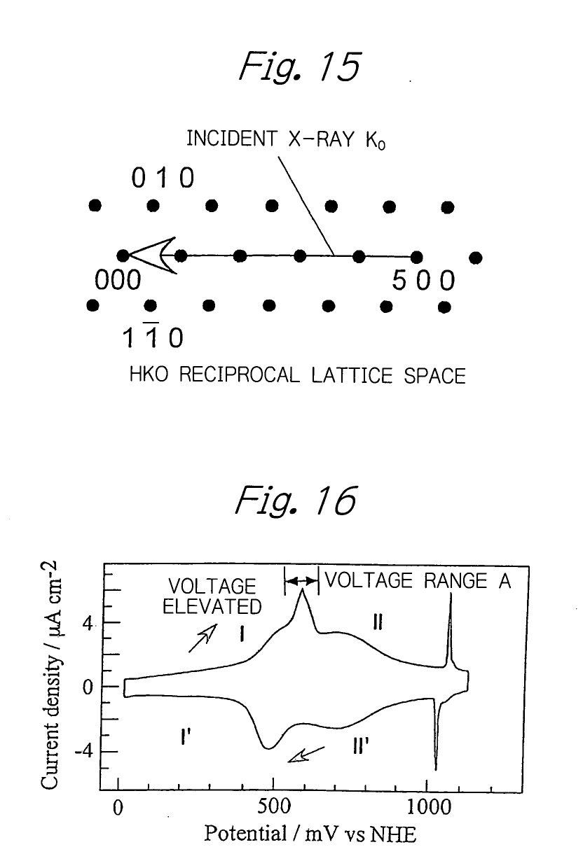

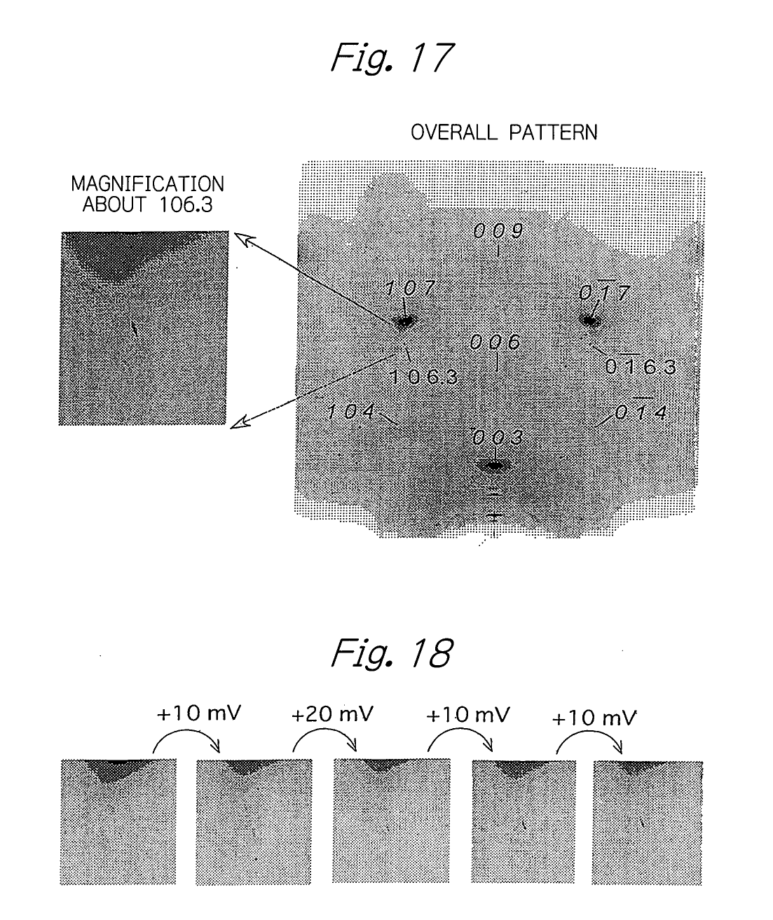

A gold (Au) (111)_{c} electrode was hydrogen annealed and then cooled to room temperature in an argon atmosphere before the electrolytic bath was filled with 0.5 M sulfuric acid (H₂SO₄) solution. The subscript C in (111)_{c} indicates that the indices are based on the cubic system notation. The reference electrode was made of mercury (Hg)|mercury sulfate (HgSO₄). In this Example, x-rays (λ=0.05 nm) were incident at an angle of 2.3 degrees with the sample surface in the electrolytic bath. FIG. 15 shows the experimental setup used in the measurement that was projected to a reciprocal lattice space (herein designated HK0 reciprocal lattice diagram) parallel to the sample surface. The voltage between the electrodes was cyclically varied to induce structural changes in the gold (111)_{c} electrode surface (FIG. 16 shows the resulting changes in the current density vs. voltage profile for the electrode, (i.e. cyclic voltammogram) and the x-ray diffraction images from the gold electrode surface were recorded (FIG. 17). A flat imaging plate was used as a two-dimensional x-ray detector. Both the sample and the detector were fixed in angle and position during x-ray exposure. The x-ray exposure time was 5 minutes. The right-hand picture in FIG. 17 shows the overall pattern of diffracted x-rays. HKL in non-italics represent indices for rod-shape diffraction conditions. Thermal diffuse scattering from HKL (in italics) representing the Bragg position of a bulk crystal is also shown in FIG. 17 as dim spots. The indices, for example 1 0 6.3 are based on a hexagonal surface lattice. From the symmetry of the overall pattern of those indices, the incident x-rays were found to be parallel to the [−1 1 0]direction defined on the basis of the surface lattice (i.e., parallel to the [−1 2 -1]_{c} direction by the cubic system notation). This corresponds to having done the job of converting the crystal orientation of the sample to an orthogonal coordinate system as defined for the measuring system (the job is commonly described as determining a UB matrix). In other words, a UB matrix has been determined by a single exposure to x-rays with the sample and the detector fixed in angle and position. The left-hand picture in FIG. 17 is a magnification of the vicinity of the rod-shape 1 0 6.3 diffraction condition.

As the structure at the solution/electrode interface (gold electrode's surface in solution) varied, the diffraction pattern changed (as magnified in FIG. 18). That is, the changes in the diffraction pattern that occurred from the process of phase transition in the surface structure was able to be recorded. The voltage variation was within the “voltage range A” marked in FIG. 16. The picture at the left end of FIG. 18 shows the x-ray diffraction that was able to be observed from the gold surface with a surface superstructure phase (called 23×√ 3 and labeled I in FIG. 16). With increasing voltage, a drastic change to the 1×1 structure (labeled II in FIG. 16) was observed.

(Possibility Used in Industries)

The method and apparatus of the present invention for rapid x-ray structural analysis of ultra-fine structures can be used to perform x-ray structure analysis on not only structural information about ultra-fine wire structures, thin films, ultra-fine nanochannels, electrodes in solution and other ultra-fine structures having the potential to be used as semiconductor devices, sensors, light emitting devices, catalysts, chemical reaction integrated microchip, mediums, DNA device carriers, and micro-fuel cell elements, but also structural information about surfaces of their substrate materials.

The method of the present invention for rapid x-ray structural analysis of a solution/solid interfacial structure is applicable in rapid evaluation of structural changes involved in chemical reactions (electrode reactions) in general which are caused by electron transfer on an electrode's surface layer. Since the electrode reaction is accompanied by energy conversion from chemical to electrical energy and material's conversion, the process of structural changes during the process of such conversions can be observed real-time at an atomic scale.

What is claimed is:

1. A method for rapid acquisition of the crystal structure possessed by ultra-fine nanowires grown on a substrate crystal surface.

2. A method for rapidly determining the crystal domain size or correlation length that is possessed by ultra-fine nanowires grown on a substrate crystal surface.

3. A method for rapidly analyzing the orientations ultra-fine nanowires grown on a substrate crystal surface with respect to the substrate crystal.

4. A method for knowing rapidly whether buried ultra-fine nanolines or nanowires as sandwiched between a substrate crystal and an overlying cap layer are crystalline and, if so, rapidly determining their crystal structure.

5. A method for rapidly determining the crystal domain size or correlation length that is possessed by buried ultra-fine nanolines or nanowires as sandwiched between a substrate crystal and an overlying cap layer and which are measured in the direction of the lines or wires.

6. A method for rapidly analyzing the orientations buried ultra-fine nanolines or nanowires as sandwiched between a substrate crystal and an overlying cap layer with respect to the substrate crystal.

7. A method for rapidly analyzing the crystal structure of a thin-film crystal, its crystal domain size, and the proportion of any differently oriented crystal domains that may be present.

8. A method for rapidly analyzing the structures of ultra-fine structures such as ultra-fine nanolines or nanowires grown on a substrate crystal surface, buried ultra-fine nanolines or nanowires as sandwiched between a substrate surface and an overlying cap layer, or thin-film crystals, which method comprises the steps of:
applying 0.1 nm or shorter-wavelength x-rays to evaluating or characterizing the surfaces of said ultra-fine structures at an angle of a few degrees or less; and
recording the diffracted x-rays in a two-dimensional x-ray detector in one action within a very short period of time, thereby allowing the intensities of the diffracted x-rays from said ultra-fine structures to be visualized in the reciprocal lattice space.

9. The method according to claim 8, wherein by taking particular note of the unique shapes of said ultra-fine structures which are such that if they are in the form of wires, the diffraction conditions resulting from the crystalline ultra-fine structures are for the shape of a sheet (sheet-shape diffraction conditions) and that if the ultra-fine structures are in the form of a thin film, the diffraction conditions resulting from the crystalline ultra-fine structures are for the shape of a rod (rod-shape diffraction conditions), crystallographic structural information for the ultra-fine structures as to whether they are crystalline, as well as concerning their crystal structure, crystal domain size (correlation length), the orientations to the substrate, and the periodicity, if any, of an array of said ultra-fine structures, are rapidly obtained.

10. The method according to claim 9, wherein the job of converting the crystal orientations of the sample to an orthogonal coordinate system as defined for the measuring system (e.g. laboratory system), which is an essential step in structural analysis and measurement of the crystal and described as determining a UB matrix, can be achieved by a single exposure to x-rays with the sample and a detector fixed in angle and position.

11. An apparatus for rapid x-ray structural analysis of structures which comprises an incident angle changing mechanism that controls the angle a sample's surface forms with an incident x-ray, a table that adjusts the height of that mechanism, a table for adjusting the height of the sample, a two-dimensional detector, a support of the two-dimensional detector, and a sample holder, said two-dimensional detector being installed in a cylinder of which center axis passes through the sample position and which can be installed to the vertical position or horizontal position. The detector can be installed at any angular position within the range of 360 degrees about the axis of the cylindrical holder. The overall image of diffraction intensity profile can be measured without rotating the sample.

12. An apparatus for rapid acquisition of the crystal structure possessed by ultra-fine nanolines or nanowires grown on a substrate crystal surface.

13. An apparatus for rapidly determining the crystal domain size or correlation length that is possessed by ultra-fine nanolines or nanowires grown on a substrate crystal surface.

14. An apparatus for rapidly analyzing the orientations ultra-fine nanolines or nanowires grown on a substrate crystal surface with respect to the substrate crystal.

15. An apparatus for knowing rapidly whether buried ultra-fine naolines or nanowires as sandwiched between a substrate crystal and an overlying cap layer are crystalline and, if so, rapidly determining their crystal structure.

16. An apparatus for rapidly determining the crystallite size or correlation length that are possessed by buried ultra-fine nanolines or nanowires as sandwiched between a substrate crystal and an overlying cap layer and which are measured in the direction of the lines or wires.

17. An apparatus for rapidly analyzing the orientations buried ultra-fine nanolines or nanowires as sandwiched between a substrate crystal and an overlying cap layer with respect to the substrate crystal.

18. An apparatus for rapidly analyzing the crystal structure of a thin-film crystal.

19. An apparatus for rapidly analyzing the crystal structure of a thin-film crystal, its crystal domain size, and the proportion of any differently oriented crystal domains that may be present.

20. An apparatus for rapidly evaluating and analyzing a solution/crystal interfacial structure.

21. An apparatus with which the job of converting the crystal orientations of a sample to an orthogonal coordinate system as defined for the measuring system, which is described as determining a UB matrix, can be achieved by a single exposure to x-rays with the sample and a detector fixed in angle and position.

22. An apparatus for rapid x-ray structural analysis of ultra-fine structures which comprises an incident angle changing mechanism that controls the angle a sample's surface forms with an incident x-ray, a table that adjusts the height of that mechanism, a table for adjusting the height of the sample, a two-dimensional detector, a support of the two-dimensional detector, and a sample holder, said two-dimensional detector being installed in a cylinder of which center axis passes through the sample position and which can be installed to the vertical position or horizontal position. The detector can be installed at any angular position within the range of 360 degrees about the axis of the cylindrical holder. The camera length as specified by the distance between the sample and the two-dimensional detector can be changed by using cylinders of different inside diameters, wherein the two-dimensional detector may be used at any position if it is of a planar type, with optional addition of a mechanism for effecting rotation about the normal to the sample surface and a cross sample transportation table, wherein sample size that can be measured ranges from 3 mm long, 3 mm wide and 0.05 mm thick to 120 mm long, 120 mm wide and 20 mm thick, the sample mass that can be measured is up to 5 kg, the camera length that can be adopted ranges from 50 mm to 250 mm, the incident angle changing mechanism permits angular adjustment within ±5 degrees including the critical angle for total external reflection of x-rays from the sample, and wherein the sample height adjusting table is capable of intercepting the incident x-ray beam at half its height by the sample placed on the horizontal.

23. A method for rapid x-ray structural analysis of a solution/solid interfacial structure, which comprises evaluating rapidly whether crystals are present on a solid surface in solution, namely, at the solution/solid interface.

24. The method according to claim 23, which can rapidly evaluate the crystal structure on a solid surface in solution, namely, at the solution/solid interface.

25. The method according to claim 23, which can rapidly determine the crystal domain size or correlation length on a solid surface in solution, namely, at the solution/solid interface.

26. The method according to claim 23, which can rapidly determine the structure of atomic or molecular ions in the vicinity of a solid surface in solution, namely, at the solution/solid interface, or in the interfacial double layer.

27. The method according to claim 23, which can rapidly observe the changes in a crystalline electrode's surface structure at varying electrode potentials that accompany the electrochemical reaction occurring at said electrode surface.

28. The method according to claim 23, wherein to two- or one-dimensional ultra-fine structures that are present on a solid surface in solution, namely, at the solution/solid interface, 0.1 nm or shorter-wavelength x-rays are applied to evaluating or characterizing their surfaces at an angle of no more than 5 degrees as the precision of the angle their surfaces form with the incident x-ray is controlled to be about 0.1 degree by means of controlling the incident angle changing mechanism and a table for adjusting the height of said structures and wherein the diffracted x-rays are recorded in a two-dimensional x-ray detector, whereby the intensities of the diffracted x-rays from said ultra-fine structures are directly visualized in the reciprocal lattice space, and their structures are rapidly analyzed.

29. The method according to claim 28, wherein those structural changes involved in chemical reactions (electrode reactions) which are caused by electron transfer on an electrode's surface layer in solution are rapidly evaluated, whereby the process of structural changes during the process of energy conversion from chemical to electrical energy or material's conversion that accompany the electrode reaction can be observed real-time at an atomic scale.
